(19) United States
(12) Patent Application Publication
(10) Pub. No.: US 2026/0107762 A1
(43) Pub. Date: Apr. 16, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Hsu-Wei Liu, Taichung City (TW); Ting-Ya LO, Hsinchu (TW); Zi Yi Yang, Taichung City (TW); Hsin-Yen Huang, New Taipei City (TW); Hsiao-Kang Chang, Hsinchu City (TW)

(73) Assignee: Taiwan Semiconductor Manufacturing Company, Ltd., Hsinchu (TW)

(21) Appl. No.: 18/912,452

(22) Filed: Oct. 10, 2024

(51) Int. Cl. H01L 23/532; H01L 21/762; H01L 21/768; H01L 23/528

(52) U.S. Cl. CPC H10W 20/48; H10W 10/014; H10W 10/17; H10W 20/076; H10W 20/435

(57) ABSTRACT

A semiconductor device includes an interconnect structure including a dielectric structure. The dielectric structure includes a metal-organic dielectric layer, an air gap and an insulating sustaining layer. The insulating sustaining layer surrounds the metal-organic dielectric layer and the insulating sustaining layer is disposed between the metal-organic dielectric layer and the air gap.

### BACKGROUND

The semiconductor integrated circuit (IC) industry has experienced a fast-paced growth. Technological advances in IC materials and design have produced generations of ICs where each generation has smaller and more complex circuits than the previous generation. The quality of the IC may be improved through material selection or structural adjustments.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1K illustrate various cross-sectional views of a method of forming a semiconductor device according to some embodiments.

FIG. 2 illustrates a cross-sectional view of a semiconductor device according to some embodiments.

FIG. 3 illustrates a various top view of a semiconductor device according to some embodiments.

FIG. 4 illustrates a cross-sectional view of a semiconductor device according to some embodiments.

FIG. 5A to FIG. 5C illustrate various cross-sectional views of a method of forming a semiconductor device according to some embodiments.

FIG. 6A to FIG. 6C illustrate various cross-sectional views of a method of forming a semiconductor device according to some embodiments.

FIG. 7 illustrates a cross-sectional view of a semiconductor device according to some embodiments.

FIG. 8 illustrates a cross-sectional view of a semiconductor device according to some embodiments.

FIG. 9 illustrates a flowchart of a method of forming a semiconductor device according to some embodiments.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

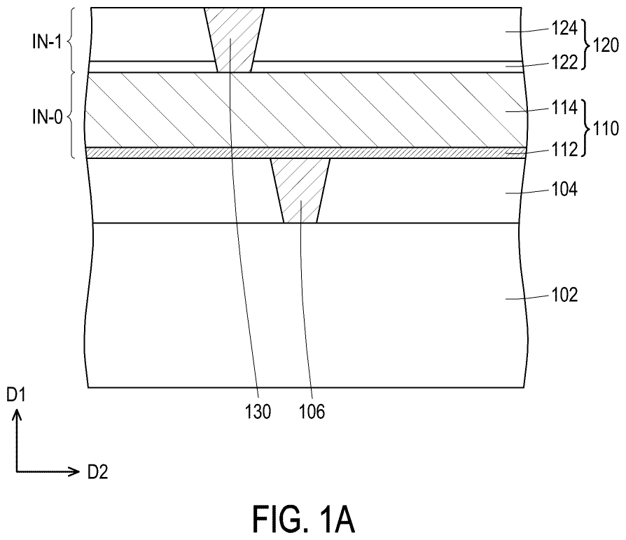

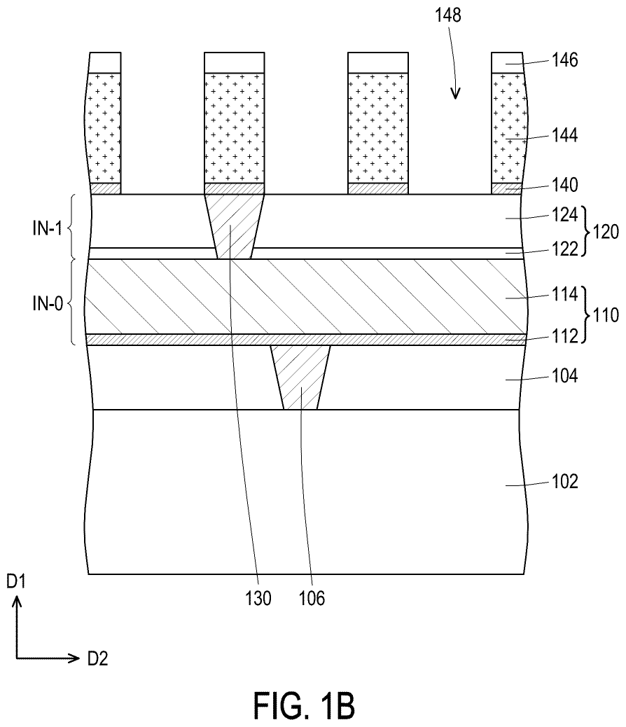

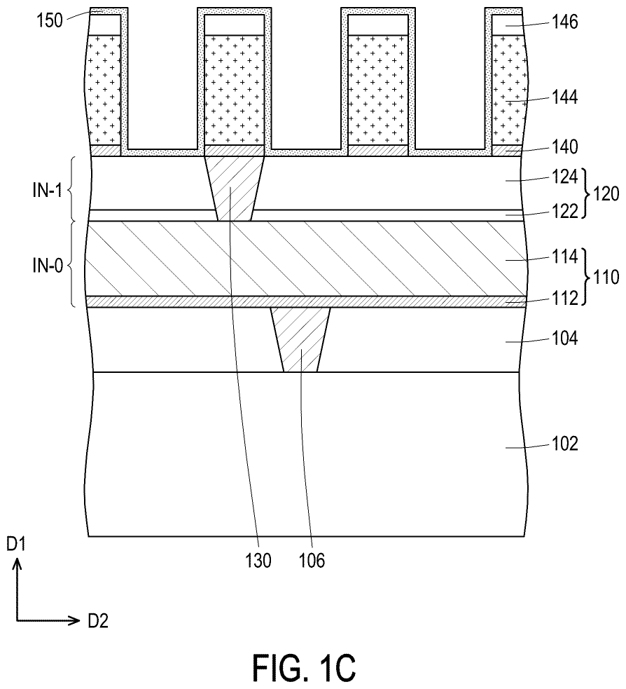

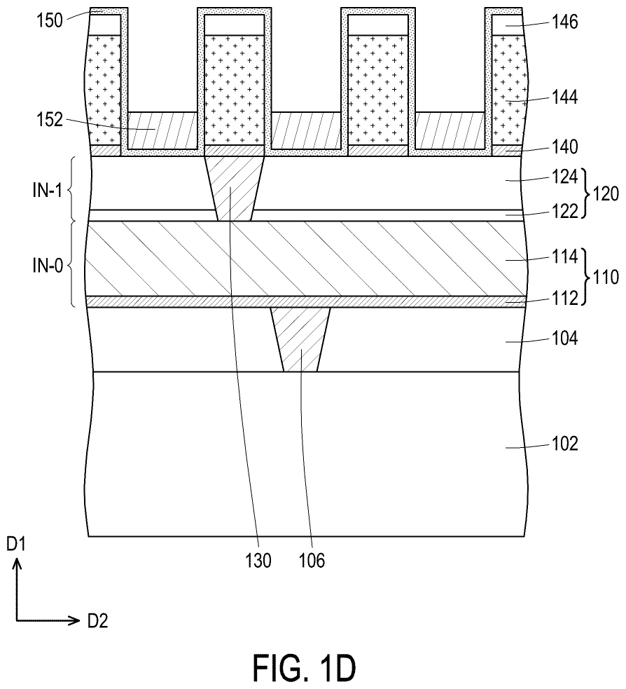

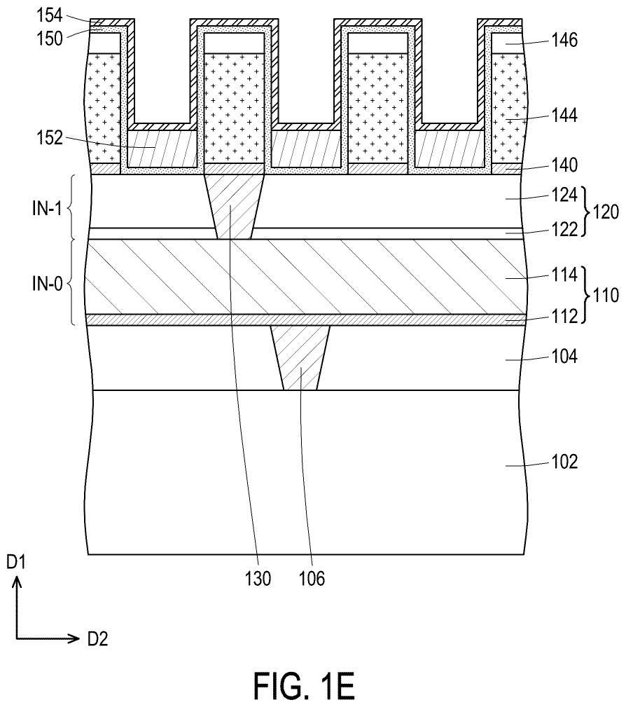

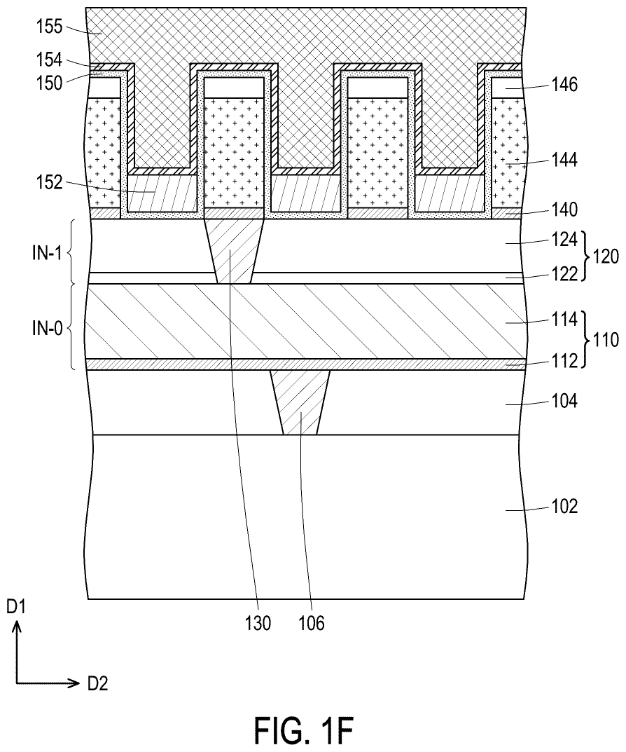

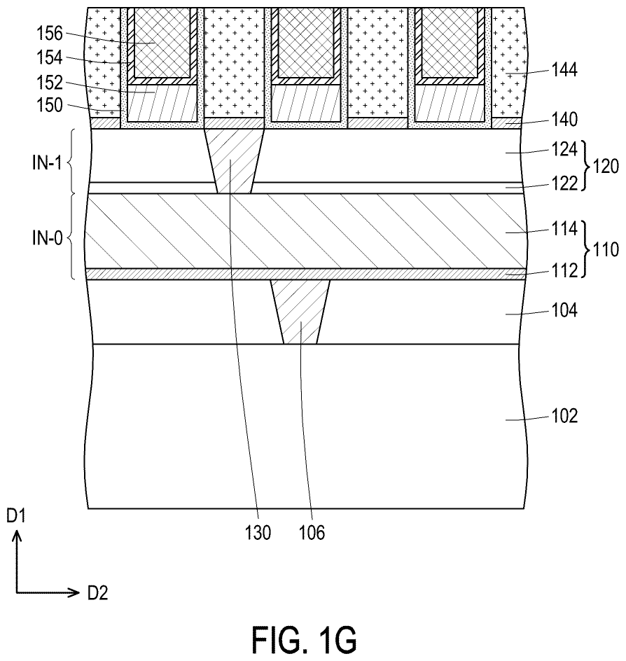

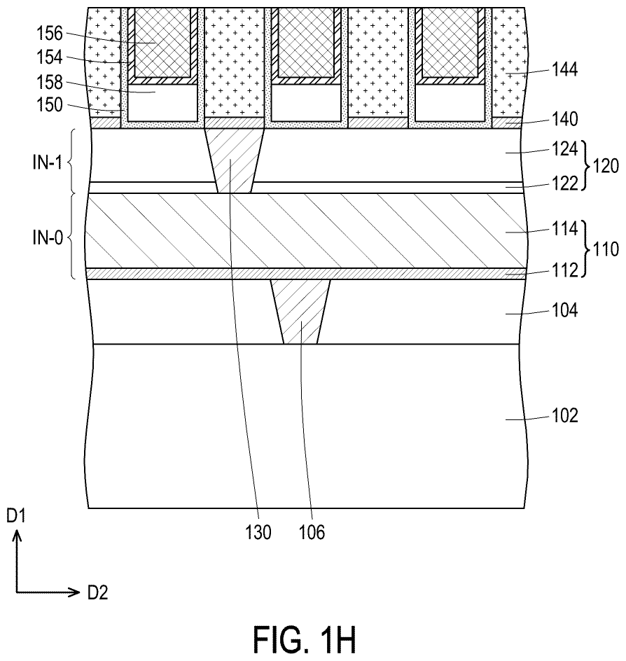

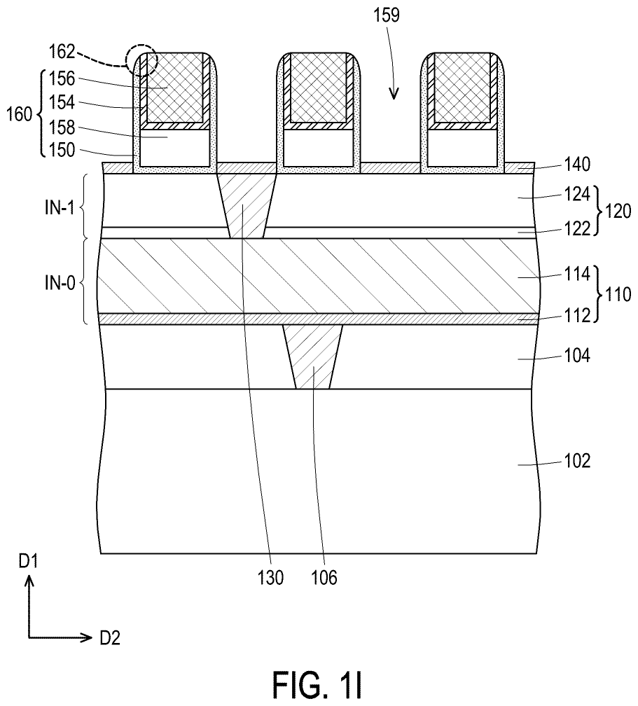

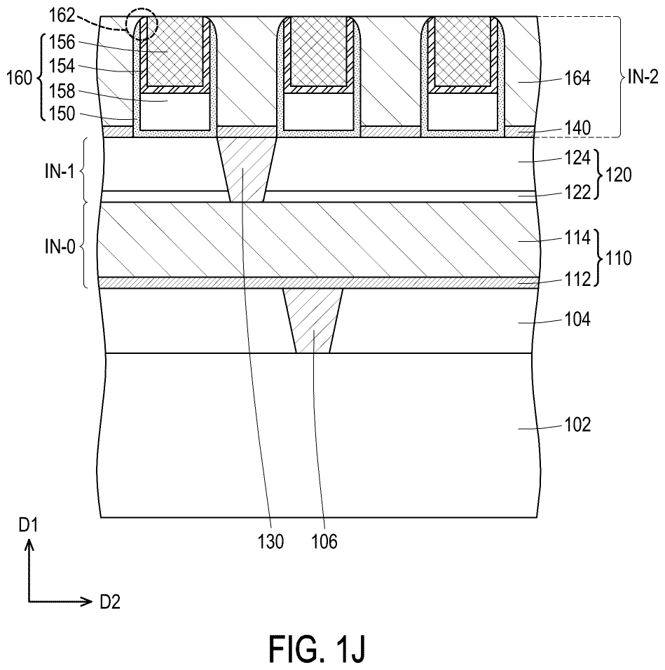

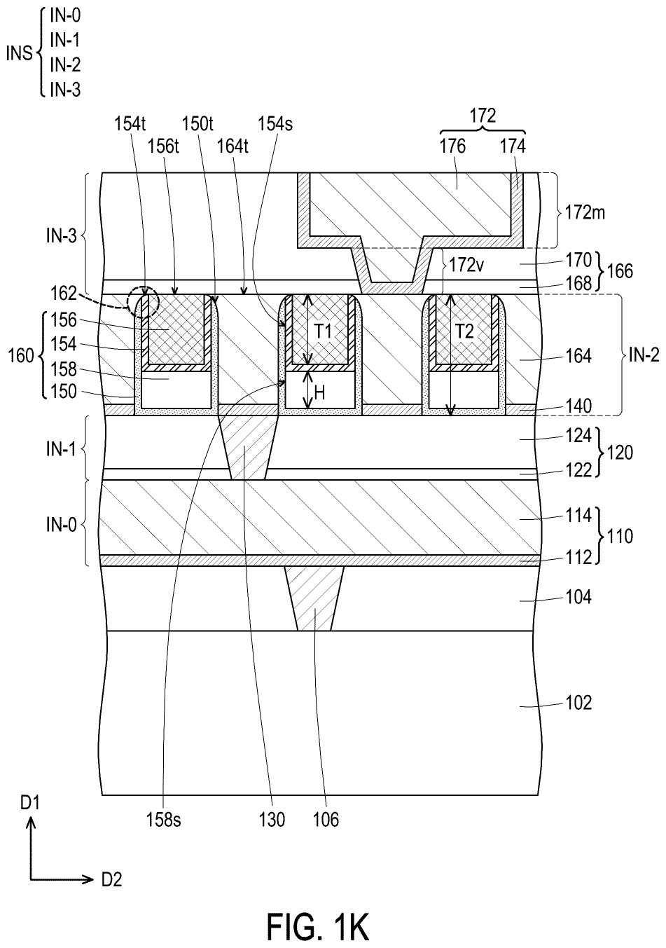

FIG. 1A to FIG. 1K illustrate various cross-sectional views of a method of forming a semiconductor device according to some embodiments.

Referring to FIG. 1A, a conductive feature 130 is formed over a substrate 102. In some embodiments, the conductive feature 130 is formed in a dielectric structure 120 over the substrate 102 along a first direction D1. The conductive feature 130 may be further electrically connected to a conductive feature 110 therebeneath. The conductive feature 110 may be disposed on and/or in the substrate 102. The first direction D1 may be vertical direction, and a second direction D2 and a third direction D3 substantially perpendicular to the first direction D1 may be horizontal direction. For example, the first direction D1 is z-direction, the second direction D2 is x-direction and the third direction D3 is y-direction. In some embodiments, the conductive feature 130 is a conductive via (e.g., via 0 (V0) layer, via 1 (V1) layer, via 2 (V2) layer, via 3 (V3) layer . . . via (x−1)(V(x−1)) layer) of an interconnect layer IN-1, and the conductive feature 110 is a conductive line (e.g., metal 0 (M0) layer, metal 1 (M1) layer, metal 2 (M2) layer, metal 3 (M3) layer . . . metal x (Mx) layer) of an interconnect layer IN-0 directly under the conductive feature 130. For example, the conductive feature 130 is via 0 (V0) layer, and the conductive feature 110 is a metal 0 (M0) layer. However, the disclosure is not limited thereto. The conductive feature 110 and the conducive feature 130 may be any two stacked conductive features. In some embodiments, the via is defined as having an aspect ratio larger than the conductive line.

In some embodiments, the dielectric structure 120 includes an etch stop layer 122 on the substrate 102 and a dielectric layer 124 on the etch stop layer 122. The conductive feature 130 may penetrate through the etch stop layer 122 and the dielectric layer 124. For example, a top surface of the conductive feature 130 is substantially coplanar with a top surface of the dielectric layer 124, and a bottom surface of the conductive feature 130 is substantially coplanar with a bottom surface of the etch stop layer 122. The conductive feature 110 is disposed in a dielectric structure (not shown) over the substrate 102. The conductive feature 110 may include a conductive layer 112 and a conductive layer 114 on the conductive layer 112, and the conductive layer 112 and the conductive layer 114 may have the same or similar pattern. In some embodiments, the conductive layer 112 is also referred to as seed layer, conductive glue layer, or barrier layer, and the conductive layer 114 is also referred to as plated layer. The conductive feature 110 may be further electrically connected to a conductive feature 106 therebeneath. The conductive feature 106 may be disposed in and/on the substrate 102. For example, the conductive feature 106 is disposed in a dielectric layer 104 over the substrate 102. The conductive feature 106 may be a plug electrically connected to an electrode (e.g., a gate electrode, a source electrode or a drain electrode) of a transistor (not shown) in and/on the substrate 102. However, the disclosure is not limited thereto.

The etch stop layer 122 may include a dielectric material, such as silicon nitride, silicon oxide, silicon oxynitride, or the like. In some embodiments, the dielectric layer 104, 124 includes low-k dielectric material. The low-k dielectric material has a dielectric constant (k) lower than silicon oxide, such as fluorine-doped silicon dioxide, organosilicate glass, carbon-doped oxide, porous silicon dioxide, porous organosilicate glass, metal organic framework (MOF), a polymer (e.g., polybenzoxazole (PBO), polyimide or a benzocyclobuten (BCB) based polymer) or the like. In alternative embodiments, the dielectric layer 104, 124 includes oxides such as silicon oxide or aluminum oxide; nitrides such as silicon nitride; carbides such as silicon carbide; a combination thereof such as silicon oxynitride, silicon oxycarbide, silicon carbonitride, silicon oxycarbonitride; or the like. In an embodiment, the dielectric layer 104 includes silicon oxide, and the dielectric layer 124 includes low-k dielectric material. The dielectric layer 104, 124 and the etch stop layer 122 may be formed by CVD process, ALD process, MLD process, spin-on process or the like. A thickness of the dielectric structure 120 is in a range of 50 Å to 700 Å, for example. The conductive feature 106, 110, 130 may be formed of a conductive material such as metal. The metal includes Cu, Co, Ru, Mo, Cr, W, Mn, Rh, Ir, Ni, Pd, Pt, Ag, Au, Al, the like, or an alloy thereof. The conductive feature 106, 110, 130 may be formed by a deposition process such as PVD process, CVD process and ALD process and a damascene process such as single-damascene process or the like. In alternative embodiments, the conductive feature 110 and the conductive feature 106 therebelow may be formed by a dual-damascene process. In such embodiments, the conductive feature 110 and the conductive feature 106 are integrally formed. A thickness of the conductive feature 106, 110, 130 is in a range of 50 Å to 500 Å, for example.

The substrate 102 may be a substrate of doped or undoped silicon. In some embodiments, the substrate 102 include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used. The substrate 102 includes a package region, for example. In alternative embodiments, the substrate 102 is a wafer substrate and includes a plurality of package regions, which will be singulated in subsequent processing. In some embodiments, the substrate 102 further includes a device layer, and the device layer includes active devices (e.g., transistors, diodes), passive devices (e.g., capacitors and resistors) the like, or a combination thereof therein and/or thereon. The substrate 102 may further include various doped regions. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. The device layer and/or a circuitry electrically connected thereto may be fabricated by a front end of line (FEOL) process. For example, the conductive feature 106 is fabricated by a FEOL process, and the conductive features 110 and 130 are fabricated by a back-end of line (BEOL) process.

Referring to FIG. 1B, a plurality of sacrificial patterns 144 and a plurality of trenches 148 between the sacrificial patterns 144 are formed over the dielectric structure 120. In some embodiments, a conductive layer 140 is further formed between the interconnect layer IL-1 and the sacrificial pattern 144. The conductive layer 140 may be also referred to as glue layer and may provide good adhesion to the conductive feature 130. In addition, the conductive layer 140 may also provide good adhesion to the dielectric capping layer 150 (shown in FIG. 1C) and the conductive feature 164 (shown in FIG. 1J) to be formed. The conductive layer 140 includes Ta, Ti, tantalum nitride (TaN), titanium nitride (TiN), the like, or a combination thereof, and is formed by a deposition process such as PVD process, CVD process and ALD process. A thickness of the conductive layer 140 is in a range of 2 Å to 100 Å, for example.

In some embodiments, the sacrificial pattern 144 is formed on the conductive layer 140, and a hard mask layer 146 is formed on the sacrificial pattern 144. The conductive layer 140, the sacrificial pattern 144 and the hard mask layer 146 are stacked and sidewalls of the conductive layer 140, the sacrificial pattern 144 and the hard mask layer 146 are substantially flush, for example. The sacrificial pattern 144 includes a sacrificial metal such as Ti, N, W, C, the like, or an alloy thereof, and the sacrificial pattern 144 is formed by a deposition process such as PVD process, CVD process and ALD process. In some embodiments, the sacrificial pattern 144 is also referred to as sacrificial metal. The material of the sacrificial pattern 144 may have an etching selectivity with respect to the materials of the dielectric structure 120, the conductive feature 130 and the conductive layer 140. A thickness of the sacrificial pattern 144 is in a range of 50 Å to 500 Å, for example. The hard mask layer 146 may include a conductive material (e.g., titanium nitride (TiN), tantalum nitride (TaN) or amorphous carbon), an insulating material (e.g., oxide or nitride), a semiconductor material (e.g., amorphous silicon (a-Si)), the like, or a combination thereof, and the hard mask layer 146 is formed by a deposition process such as PVD process, CVD process and ALD process.

In some embodiments, the conductive layer 140, the sacrificial patterns 144 and the trenches 148 are formed by forming materials of the conductive layer 140, the sacrificial pattern 144 and the hard mask layer 146 and patterning the materials with a photolithography process. The sacrificial pattern 144 and the conductive layer 140 covers the conductive feature 130 therebeneath while the trenches 148 expose portions of the dielectric structure 120, for example.

Referring to FIG. 1C, a dielectric capping layer 150 is formed on the sacrificial patterns 144 and the trenches 148 over the dielectric structure 120. The dielectric capping layer 150 may provide protection and/or mechanical strength for the sacrificial patterns 144. The dielectric capping layer 150 may be formed on sidewalls and bottom surfaces of the trenches 148. In some embodiments, the dielectric capping layer 150 is continuously and conformally formed on sidewalls and top surfaces of the hard mask layers 146, sidewalls of the sacrificial patterns 144, sidewalls of the conductive layer 140, and surfaces (e.g., top surfaces) of the dielectric structure 120 exposed by the trenches 148. For example, the sidewalls of the conductive layer 140, the sidewalls and top surfaces of the hard mask layers 146, the sidewalls of the sacrificial patterns 144 and the surfaces (e.g., top surface) of the dielectric structure 120 are covered by the dielectric capping layer 150. In some embodiments, the conductive layer 140 provides good adhesion to the dielectric capping layer 150. In some embodiments, the dielectric material of the dielectric capping layer 150 is similar to low-k material but has a density and/or dielectric constant (k) higher than low-k dielectric material. For example, the density of the dielectric capping layer 150 is larger than 1.8 g/cm³ (e.g., in a range of 2.1 g/cm³ to 2.3 g/cm³), which is larger than the density (e.g., 1.3 g/cm³ to 1.5 g/cm³) of low-k dielectric material. The dielectric constant (k) of the dielectric capping layer 150 is in a range of 3.5 to 8.0, for example. The refractive index of the dielectric capping layer 150 is, for example, in a range of 1.5 to 1.7. In such embodiments, the dielectric capping layer 150 has enough mechanical support for the gap-fill material while allowing enough porosity for sacrificial material to pass through during burn out process. The dielectric material of the dielectric capping layer 150 may include silicon oxycarbide (SiCO), silicon oxide (SiO), silicon oxynitride (SiNO), silicon carbonitride (SiCN), silicon oxycarbonitride (SiCON), aluminum nitride (AlN), aluminum oxynitride (AlON), aluminum oxide (AlO), the like, or a combination thereof. The dielectric capping layer 150 may be formed by a deposition process such as PVD process, CVD process, ALD process, PECVD process and PEALD process. A thickness of the dielectric capping layer 150 is in a range of 2 Å to 50 Å, for example. In some embodiments, the material of the dielectric capping layer 150 has a density and/or a dielectric constant (k) higher than the dielectric structure 120 therebelow. For example, the dielectric capping layer 150 includes silicon oxycarbide (SiCO) and the dielectric structure 120 includes low-k dielectric material.

Referring to FIG. 1D, a plurality of sacrificial patterns 152 are formed in the trenches 148 respectively. A material of the sacrificial pattern 152 includes an organic material including C, O, N, H or the like. For example, the material of the sacrificial patterns 152 includes polymer such as polyurea and polyurea-like polymer. The polyurea-like polymer may be formed by the polymerization of individual monomers such as isocyanate and amine. The ratio between these monomers and the exact chemical formula for such monomers may determine the chemical properties of the polymerized film. The material of the sacrificial pattern 152 may have an etching selectivity with respect to the materials of the dielectric capping layer 150 and an insulating sustaining layer 154 to be formed (shown in FIG. 1E). The sacrificial patterns 152 may be formed by forming a sacrificial material over the sacrificial patterns 144 and in the trenches 148 and removing portions of the sacrificial material. The sacrificial material may be formed by a deposition process such as CVD process, ALD process, MLD process and spin-on process, and a height of the sacrificial material may be tuned by an etch back process, a thermal recess or the like. After tuning, a thickness of the sacrificial pattern 152 may be about 20% to 60% of a depth of the trench 148. For example, a thickness of the sacrificial pattern 152 is in a range of 10 Å to 100 Å. In some embodiments, as shown in FIG. 1D, a top surface of the sacrificial pattern 152 is lower than top surfaces of the sacrificial patterns 144, and thus portions (e.g., upper portions) of the sidewalls of the trench 148 are exposed. In some embodiments in which the dielectric capping layer 150 is formed to surround the sacrificial patterns 144, the portions of the dielectric capping layer 150 on the top surfaces of the hard mask layers 146 and on the top sidewalls of the sacrificial patterns 144 are exposed.

Referring to FIG. 1E, an insulating sustaining layer 154 is formed on the sidewalls of the sacrificial patterns 144. For example, the insulating sustaining layer 154 is continuously formed on the top surfaces of the hard mask layers 146, the top sidewalls of the sacrificial patterns 144 and the top surfaces of the sacrificial patterns 152.

A material of the insulating sustaining layer 154 may include silicon oxide (SiO), silicon carbon oxide (SiCO), silicon oxynitride (SiNO), silicon carbon nitride (SiCN), nitride-doped silicon oxide (SiCON). The insulating sustaining layer 154 may be formed by a deposition process such as CVD process and ALD process. A thickness of the insulating sustaining layer 154 is in a range of 2 Å to 50 Å, and in a range of 10 Å to 30 Å, for example. In some embodiments, the material of the insulating sustaining layer 154 has a low density in a range of 2.1 g/cm³ to 2.5 g/cm³. For example, the insulating sustaining layer 154 is a loose porous silicon oxide layer formed by a low temperature in a range of 50° C. to 100° C.

Referring to FIG. 1F, a metal-organic dielectric material 155 is formed in the trenches 148. For example, the metal-organic dielectric material 155 is formed over the dielectric structure 120 to cover the sacrificial patterns 144 and the sacrificial patterns 152 and fills up the trenches 148. The metal-organic dielectric material 155 may include a dielectric constant (k) smaller than low-k material and may be also referred to as an ultra-low-k material. For example, the dielectric constant (k) of the metal-organic dielectric material 155 is smaller than 2.5. The metal-organic dielectric material 155 may be a porous material. In some embodiments, the metal-organic dielectric material 155 includes a metal organic framework (MOF) such as zeolitic imidazolate framework (ZIF). The metal-organic dielectric material 155 may be formed by depositing a metal oxide precursor and converting the metal oxide precursor. The metal oxide precursor may include an oxide of a metal such as Zn, Sr, Pb, Mn, Co, Pb, the like or a combination thereof. The metal oxide precursor may be formed by providing a compound of the metal and a solvent such as water and methanol. A thickness of the metal oxide precursor may be in a range of 2 nm to 6 nm. The metal oxide precursor may be then converted to a metal-organic dielectric layer by providing organic linker such as imidazole based linker. A thickness of the metal-organic dielectric material 155 may be in a range of 8 nm to 24 nm. For example, zinc oxide (ZnO) layer is deposited, and then zinc oxide (ZnO) layer is converted to a metal-organic dielectric layer by providing 2-methyl imidazolate vapor. However, the disclosure is not limited thereto. The metal-organic dielectric layer may include suitable metal other than Zn. In some embodiments, the metal-organic dielectric material 155 is also referred to as gap-fill metal-organic dielectric layer or metal-organic framework dielectric layer.

Referring to FIG. 1G, portions of the metal-organic dielectric material 155 are removed, to form a plurality of metal-organic dielectric layers 156. For example, the portions of the metal-organic dielectric material 155 and the hard mask layers 146 higher than the sacrificial patterns 144 are removed. In some embodiments, the hard mask layers 146 and portions of the insulating sustaining layer 154 and the dielectric capping layer 150 are also removed, to expose top surfaces of the sacrificial patterns 144. Top surfaces of the metal-organic dielectric layers 156 are substantially coplanar with the top surfaces of the sacrificial patterns 144, the insulating sustaining layer 154 and the dielectric capping layer 150, for example. The removal may be performed by a planarization process such as chemical mechanical planarization (CMP) process or any suitable process.

Referring to FIG. 1H, the sacrificial patterns 152 are removed to form a plurality of air gaps 158 directly below the metal-organic dielectric layers 156. In some embodiments, the sacrificial patterns 152 are removed after the removal of the hard mask layers 146 and the formation of the metal-organic dielectric layers 156. The sacrificial patterns 152 may be removed by a thermal process such as a thermal baking process, an UV curing process or the like. In some embodiments, since both the density of the metal-organic dielectric layers 156 and the insulating sustaining layer 154 is low, the sacrificial patterns 152 are removed by evaporating through the metal-organic dielectric layers 156 and the insulating sustaining layer 154 when heating by the thermal process. In other words, the sacrificial patterns 152 may be removed with the presence of the metal-organic dielectric layers 156 and the insulating sustaining layer 154 thereabove. In alternative embodiments, an additional UV curing may be performed to ensure complete removal of sacrificial material without any residual carbon content in the trench 159 (shown in FIG. 1I). In some embodiments, since the material of the sacrificial pattern 152 has an etching selectivity with respect to the materials of the sacrificial pattern 144, the metal-organic dielectric layer 156, the insulating sustaining layer 154 and the dielectric capping layer 150, the sacrificial pattern 144, the metal-organic dielectric layer 156, the insulating sustaining layer 154 and the dielectric capping layer 150 may be substantially intact after performing the removal process of the sacrificial patterns 152. As shown in FIG. 1H, the air gap 158 is surrounded by the dielectric capping layer 150 and the insulating sustaining layer 154 below the metal-organic dielectric layer 156, for example.

Referring to FIG. 1I and FIG. 1J, the sacrificial patterns 144 are replaced with conductive features 164. As shown in FIG. 1I, the sacrificial patterns 144 are removed to form trenches 159 between the metal-organic dielectric layers 156 and between the air gaps 158. The sacrificial patterns 144 may be removed by an etch process such as wet etch process or dry etch process or the like. For example, the sacrificial patterns 144 are removed by using an H₂O₂ based etchant or the like. In some embodiments, since the material of the sacrificial pattern 144 has an etching selectivity with respect to the materials of the metal-organic dielectric layer 156, the insulating sustaining layer 154 and the dielectric capping layer 150, the metal-organic dielectric layer 156, the insulating sustaining layer 154 and the dielectric capping layer 150 may be substantially intact after performing the removal process of the sacrificial patterns 144. In some embodiments, the metal-organic dielectric layer 156 and the air gap 158 therebelow are collectively referred to as dielectric structure 160. The dielectric structure 160 may further include the insulating sustaining layer 154 surrounding the metal-organic dielectric layer 156 and the dielectric capping layer 150 surrounding the insulating sustaining layer 154, the metal-organic dielectric layer 156 and the air gap 158. For example, the insulating sustaining layer 154 is disposed on the sidewalls and the bottom surface of the metal-organic dielectric layer 156, and the dielectric capping layer 150 is disposed on the sidewalls of the metal-organic dielectric layer 156 and the air gap 158 and the bottom of the air gap 158.

In some embodiments, since the metal-organic dielectric layer 156 may provide structural robustness, the sacrificial patterns 144 are removed after the removal of the sacrificial patterns 152. However, the disclosure is not limited thereto. In alternative embodiments, the sacrificial patterns 144 is removed before the removal of the sacrificial patterns 152.

In some embodiments, portions of the dielectric structure 160 are removed, so that the dielectric structure 160 has rounded corners 162. For example, upper portions of the insulating sustaining layer 154 and the dielectric capping layer 150 (and optionally the metal-organic dielectric layer 156) are partially removed, and thus the dielectric structure 160 has the rounded corners 162. The upper sidewall of the insulating sustaining layer 154 and the dielectric capping layer 150 is rounded, for example. The removal of the insulating sustaining layer 154 and the dielectric capping layer 150 may be performed by an etch process such as dry etch process or wet etch process or the like. Accordingly, a top width (e.g., topmost width) of the trench 159 of the dielectric structure 160 is enlarged, which is beneficial to the formation of the conductive feature 164 of FIG. 1J.

Then, as shown in FIG. 1J, conductive features 164 are formed in the trenches 159 of the dielectric structure 160. The conductive feature 164 may be formed by a single-damascene process. For example, a conductive material is formed over the dielectric structure 160 and fill up the trenches 159, and then the conductive material outside the trenches 159 is removed. The conductive material may be removed by a planarization process such as chemical mechanical planarization (CMP) process. The conductive feature 164 is disposed in the dielectric structure 160 and electrically connected to the conductive feature 130 in the dielectric structure 120. In some embodiments, the conductive feature 164 includes a conductive layer, and the conductive layer 163 is single-layered or has a multi-layered structure. In some embodiments, the conductive layer 140 is disposed under the conductive feature 164 and between the conductive feature 164 and the interconnect layer IN-1 over the substrate 102. A sidewall of the conductive layer 140 is substantially flush with a sidewall of the conductive feature 164, for example. The conductive feature 164 may be a conductive line such as M1 layer, and the conductive feature 130 may be a conductive via such as V0 layer. In some embodiments, the dielectric structure 160 and the conductive feature 164 are collectively referred to as interconnect layer IN-2.

The dielectric structure 160 is laterally disposed between the adjacent conductive features 164. The dielectric structure 160 may have a substantially constant lateral dimension. The lateral dimension is a dimension along the direction D2, for example. In some embodiments, the lateral dimension of the dielectric structure 160 between the topmost portions of the adjacent conductive features 164 is smaller than the lateral dimension of the dielectric structure 160 between other portions of the adjacent conductive features 164 due to the rounded corner. The metal-organic dielectric layer 156 is disposed on the air gap 158. For example, the metal-organic dielectric layer 156 is laterally disposed between and electrically isolated upper portions of the adjacent conductive features 164, and the air gap 158 is laterally disposed between and electrically isolated lower portions of the adjacent conductive features 164. The air gap 158 may be referred to as space in which there may be no solid material. The gas pressure in the air gap 158 may be extremely low or close to vacuum. Accordingly, the air gap 158 may reduce signal interference or coupling capacitance between two adjacent conductive features 164. A lateral dimension of the metal-organic dielectric layer 156 between the adjacent conductive features 164 may be substantially the same as a lateral dimension of the air gap 158 between the adjacent conductive features 164. In some embodiments, the lateral dimension of the metal-organic dielectric layer 156 between the adjacent conductive features 164 is smaller than the lateral dimension of the air gap 158 between the adjacent conductive features 164.

Referring to FIG. 1K, a conductive feature 172 in a dielectric structure 166 is formed over the dielectric structure 160 and electrically connected to the conductive feature 164. In some embodiments, the dielectric structure 166 and the conductive feature 170 are collectively referred to as interconnect layer IN-3. The dielectric structure 166 may include an etch stop layer 168 and a dielectric layer 170 on the etch stop layer 168. A thickness of the dielectric structure 166 is in a range of 50 Å to 700 Å, for example. The materials and forming method of the etch stop layer 168 and the dielectric layer 170 may be similar to those of the etch stop layer 122 and the dielectric layer 124, so the detailed description thereof is omitted herein. The conductive feature 172 may include a conductive layer 174 and a conductive layer 176, and the conductive layer 174 surrounds the conductive layer 176. The conductive layer 174 is also referred to as seed layer, a conductive glue layer, or a barrier layer. The conductive layer 176 is also referred to as plated layer. A thickness of the conductive feature 172 is in a range of 50 Å to 500 Å, for example. The materials of the conductive layer 174 and the conductive layer 176 may be similar to those of the conductive layer 112 and the conductive layer 114, so the detailed description thereof is omitted herein. The conductive feature 172 may include a via 172v and a conductive line 172m on the via 172v and electrically connected to the via 172v. In some embodiments, the conductive feature 172 is formed by a dual-damascene process and the via 172v and the conductive line 172m are integrally formed. For example, the etch stop layer 168 and the dielectric layer 170 are sequentially formed over the dielectric structure 160, to form the dielectric structure 166. Then, a trench may be formed in the dielectric structure 166, and a first material of the conductive layer 174 and a material of the conductive layer 176 are formed over the dielectric structure 166 and fill up the trench. After that, the first material and the second material outside the trench may be removed, to form the conductive feature 172. The first material and the second material may be removed by a planarization process such as chemical mechanical planarization (CMP) process. However, the disclosure is not limited thereto. In alternative embodiments, the via 172v and the conductive line 172m may be respectively formed by a single-damascene process or the like. For example, the conductive line 172m and a dielectric structure surrounding the conductive line 172m are formed by the process for the interconnect layer IN-2.

In some embodiments, the interconnect layers IN-0, IN-1, IN-2, IN-3 form an interconnect structure INS. However, it is noted that the interconnect structure INS may have less or more interconnect layers. In addition, in some embodiments, only the interconnect layer IN-2 is illustrated as adopting the dielectric structure 160, the disclosure is not limited thereto. In alternative embodiments, any interconnect layer (e.g., metal 0 (M0) layer, metal 1 (M1) layer, metal 2 (M2) layer, metal 3 (M3) layer . . . metal x (Mx) layer, and via 0 (V0) layer, via 0 (V0) layer, via 1 (V1) layer, via 2 (V2) layer, via 3 (V3) layer . . . via (x−1) ( V(x−1)) layer) may adopt the dielectric structure 160, especially the interconnect layer (e.g., metal 0 (M0) layer, metal 1 (M1) layer, metal 2 (M2) layer, metal 3 (M3) layer . . . metal x (Mx) layer) in which the density of the conductive features is high. In alternative embodiments in which the dielectric layer includes a porous material such as low-k dielectric material and the damascene process is performed, the dielectric layer may be damaged due to the carbon diffusion during the etch process and the capacitance may be thus increased, which is severe when the pitch of the conductive feature is reduced. On contrary, in some embodiments, the metal-organic dielectric layer 156 is adopted, and a single-damascene process is performed to form the conductive features 164 in the dielectric structure 160. Thus, the loss of the metal-organic dielectric layer 156 may be prevented, and the capacitance would not be affected. Accordingly, the dielectric structure 160 may be used for the formation of the conductive feature with fine pitch.

In some embodiments, the interconnect layer IN-2 includes the dielectric structure 160 and the conductive features 164 in the dielectric structure 160. The dielectric structure 160 includes the metal-organic dielectric layer 156 and the air gap 158 therebelow. The air gap 158 is formed between the metal-organic dielectric layer 156 and the substrate 102, for example. For example, the dielectric capping layer 150, the insulating sustaining layer 154 and the metal-organic dielectric layer 156 surround upper portions of the conductive features 164 respectively, and the air gap 158 also surrounds lower portions of the conductive features 164 respectively. The insulating sustaining layer 154 surrounds the metal-organic dielectric layer 156. The insulating sustaining layer 154 is disposed between the metal-organic dielectric layer 156 and the conductive feature 164, between the dielectric capping layer 150 and the metal-organic dielectric layer 156 and between the metal-organic dielectric layer 156 and the air gap 158, for example. A sidewall (e.g., outer sidewall) 154s of the insulating sustaining layer 154 may be substantially flush with a sidewall 158s of the air gap 158. The dielectric capping layer 150 may surround the metal-organic dielectric layer 156 and the air gap 158 and may be disposed between the insulating sustaining layer 154 and the conductive feature 164 and between the air gap 158 and the conductive feature 164. In some embodiments, a ratio (H/T1) of a height H of the air gap 158 to a thickness T1 of the metal-organic dielectric layer 156 thereover may be in a range of 0.25 to 1.5. The thickness T1 and the height H1 are dimensions along the direction D1, for example. In some embodiments, a thickness T1 of the metal-organic dielectric layer 156 is larger than a height H1 of the air gap 158. For example, the thickness T1 of the metal-organic dielectric layer 156 is about 40% to 80% of a total thickness T2 of the conductive feature 164 and the conductive layer 140 therebeneath, and the height H1 of the air gap 158 is about 20% to 60% of a total thickness T2 of the conductive feature 164 and the conductive layer 140 therebeneath. The total thickness T2 of the conductive feature 164 is substantially equal to a thickness of the conductive feature 164, for example. However, the disclosure is not limited thereto. In alternative embodiments, the thickness T1 of the metal-organic dielectric layer 156 is smaller than or substantially equal to the height H1 of the air gap 158.

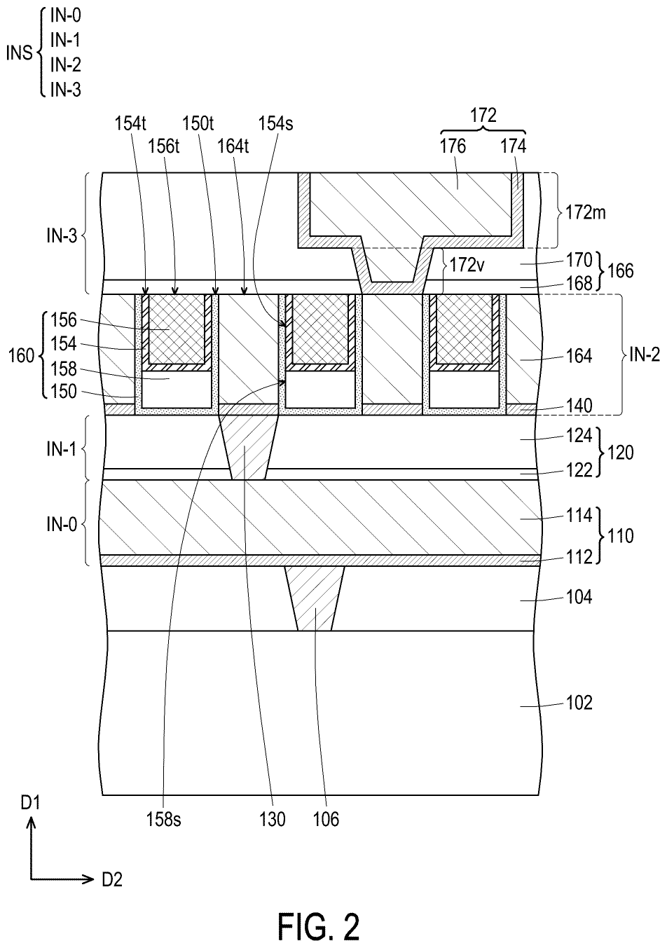

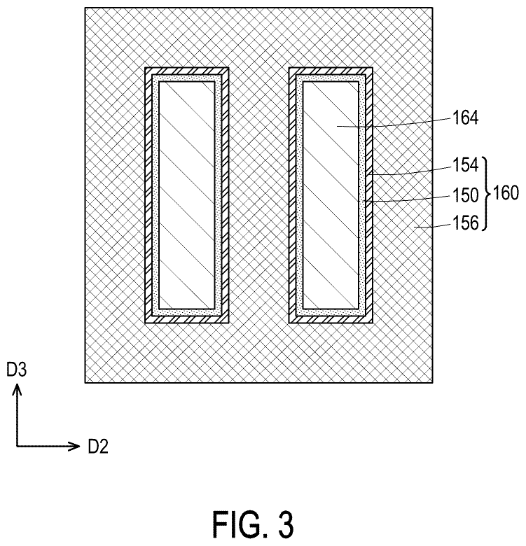

In some embodiments, a top surface of the dielectric structure 160 is substantially coplanar with a top surface of the conductive feature 164. For example, a top surface 156t of the metal-organic dielectric layer 156 is substantially coplanar with a top surface 164t of the conductive feature 164, and top surfaces 154t, 150t of the insulating sustaining layer 154 and the dielectric capping layer 150 are lowered than the top surfaces 156t, 164t of the metal-organic dielectric layer 156 and the conductive feature 164. In some embodiments, the top surface 150t of the dielectric capping layer 150 is lowered than the top surface 154t of the insulating sustaining layer 154. However, the disclosure is not limited thereto. In some embodiments in which there is no rounded corner in the dielectric structure 160, as shown in FIG. 2, the top surfaces 150t, 154t, 156t of the dielectric capping layer 150, the insulating sustaining layer 154 and the metal-organic dielectric layer 156 are substantially coplanar with the top surface 164t of the conductive feature 164. In a top view, as shown in FIG. 3, the conductive feature 164 is a conductive line and thus line-shaped, and the dielectric structure 160 surrounds the conductive features 164. For example, the dielectric capping layer 150, the insulating sustaining layer 154 and the metal-organic dielectric layer 156 surround an upper portion of the conductive feature 164 respectively.

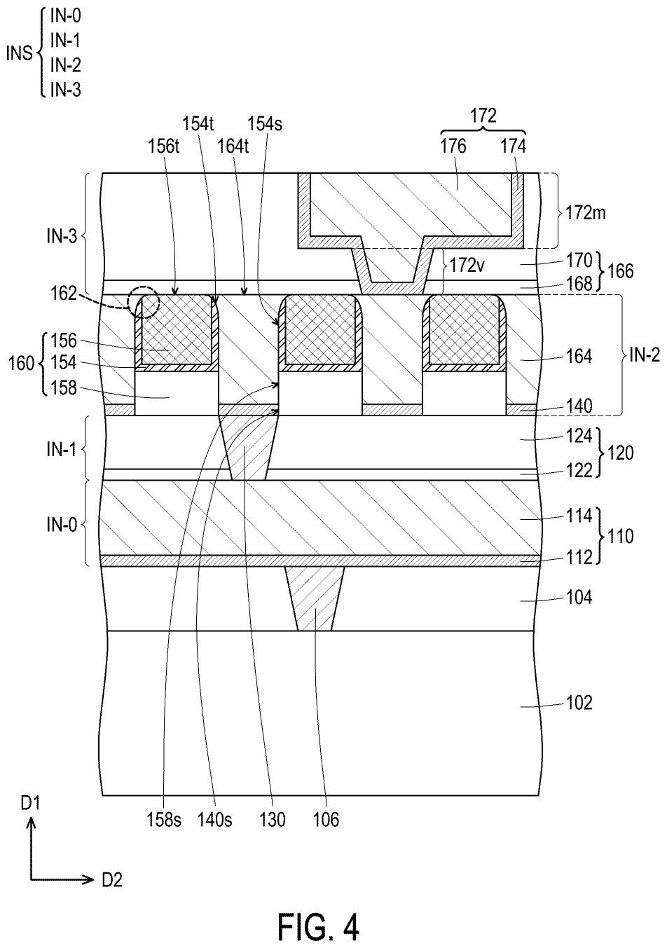

In some embodiments in which the dielectric capping layer is omitted, as shown in FIG. 4, the dielectric structure 160 includes the metal-organic dielectric layer 156, the air gap 158 and the insulating sustaining layer 154 surrounding the metal-organic dielectric layer 156 and interposed between the metal-organic dielectric layer 156 and the air gap 158. The top surfaces 154t of the insulating sustaining layer 154 may be lowered than the top surfaces 156t, 164t of the metal-organic dielectric layer 156 and the conductive feature 164. The sidewalls 140s, 154s, 158s of the conductive layer 140, the insulating sustaining layer 154 and the air gap 158 are substantially flush, for example. In alternative embodiments (not shown), the top surfaces 154t of the insulating sustaining layer 154 may be substantially coplanar with the top surfaces 156t, 164t of the metal-organic dielectric layer 156 and the conductive feature 164.

In some embodiments, the interconnect structure INS adopts the dielectric structure 160 including the metal-organic dielectric layer 156 and the air gap 158 in back-end of line (BEOL) fabrication. The effective dielectric constant (k) of the dielectric structure 160 is low and thus the capacitance may be lowered. For example, the effective dielectric constant (k) of the dielectric structure 160 is smaller than 2, which is smaller than low-k dielectric material. In addition, the capacitance reduction may be further achieved by tuning the height or ratio of the air gap 158 in the dielectric structure 160. Furthermore, the metal-organic dielectric layer 156 provides structural robustness, and thus the dielectric structure 160 incorporating the metal-organic dielectric layer 156 with the air gap 158 also has good mechanical robustness. Accordingly, the dielectric structure provides ultra-low dielectric constant (k) with low leakage current while keeping good thermal/mechanical properties than low-density amorphous material such as SiOC, low-k material and organic polymer. Accordingly, the semiconductor device may have an improved performance and/or quality.

In some embodiments, the sacrificial patterns 152 are removed after the removal of the sacrificial patterns 144. However, the disclosure is not limited thereto.

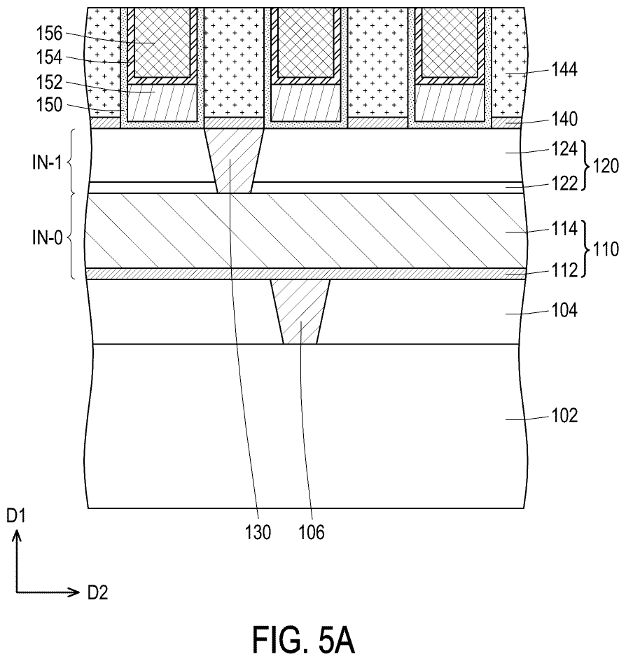

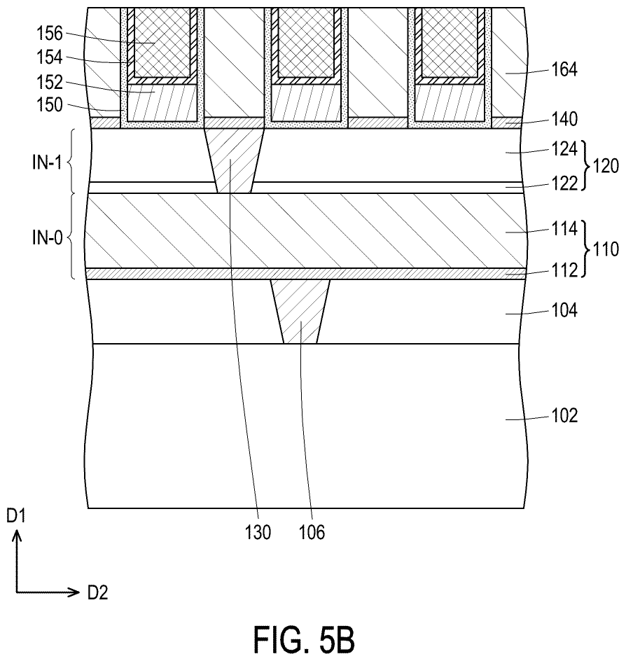

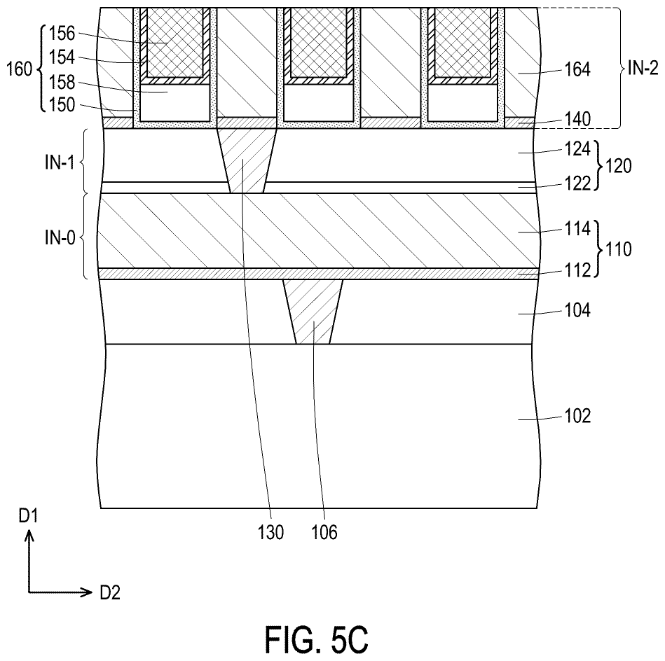

FIG. 5A to FIG. 5C illustrate various cross-sectional views of a method of forming a semiconductor device according to some embodiments.

Referring to FIG. 5A, a structure of FIG. 1G is provided. In some embodiments, the metal-organic dielectric layers 156 are disposed on the sacrificial patterns 152 respectively, and the sacrificial patterns 144 are disposed between the metal-organic dielectric layers 156 and between the sacrificial patterns 152.

Referring to FIG. 5B, the sacrificial patterns 144 are replaced with conductive features 164. The replacement of the sacrificial patterns 144 is similar to that described with respect to FIG. 1I and FIG. 1J, so the detailed description thereof is omitted herein. In some embodiments, the conductive features 164 are disposed between the metal-organic dielectric layers 156 and between the sacrificial patterns 152. In some embodiments, since the material of the sacrificial pattern 144 has an etching selectivity with respect to the materials of the metal-organic dielectric layer 156, the insulating sustaining layer 154 and the dielectric capping layer 150, the metal-organic dielectric layer 156, the insulating sustaining layer 154 and the dielectric capping layer 150 may be substantially intact after performing the removal process of the sacrificial patterns 144.

Referring to FIG. 5C, after the conductive features 164 are formed, the sacrificial patterns 152 are removed to form air gaps 158. The removal of the sacrificial patterns 152 is similar to that described with respect to FIG. 1H, so the detailed description thereof is omitted herein. In some embodiments, the air gaps 158 are formed after the formation of the conductive features 164. In some embodiments, since the material of the sacrificial pattern 152 has an etching selectivity with respect to the materials of the metal-organic dielectric layer 156, the insulating sustaining layer 154 and the dielectric capping layer 150 and the conductive features 164, the metal-organic dielectric layer 156, the insulating sustaining layer 154 and the dielectric capping layer 150 and the conductive features 164 may be substantially intact after performing the removal process of the sacrificial patterns 144, for example.

Then, a conductive feature 172 in a dielectric structure 166 is formed over the dielectric structure 160 and electrically connected to the conductive feature 164, to form an interconnect structure INS of FIG. 2 (without rounded corner). In alternative embodiments, after the sacrificial patterns 144 are removed and before the conductive features 164 are formed, portions of the dielectric structure 160 are removed, so that the dielectric structure 160 have rounded corners 162. In such embodiments, the semiconductor device of FIG. 1K is formed.

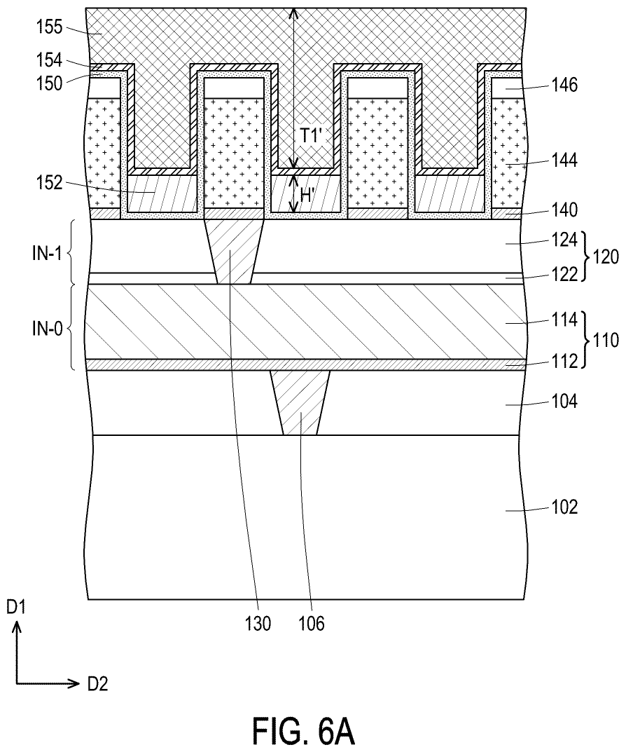

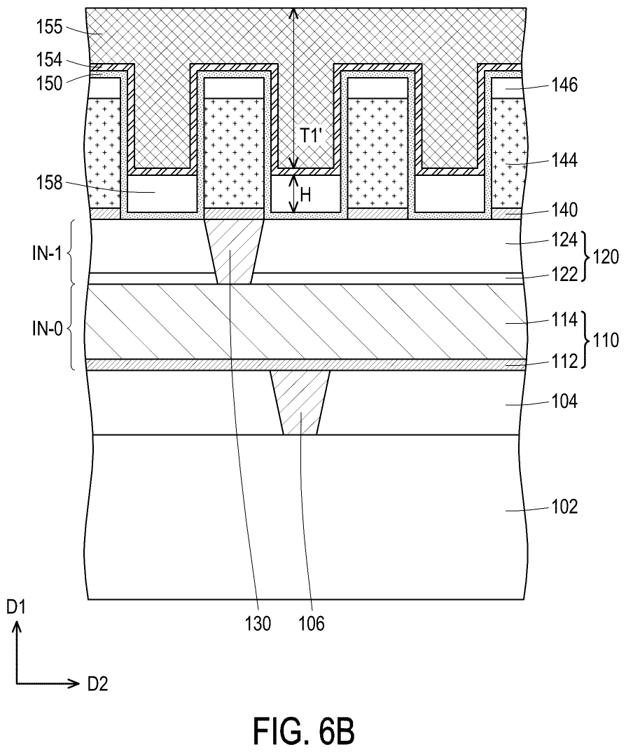

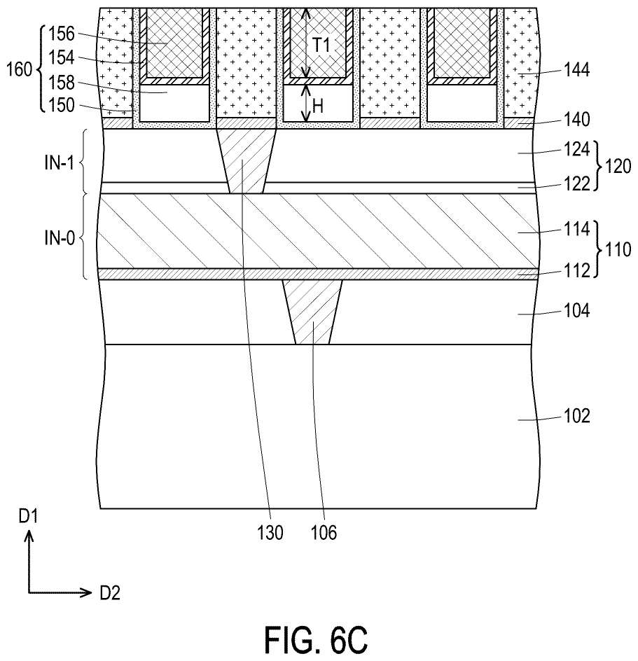

FIG. 6A to FIG. 6C illustrate various cross-sectional views of a method of forming a semiconductor device according to some embodiments.

Referring to FIG. 6A, a structure similar to FIG. 1F is provided. In some embodiments, the metal-organic dielectric material 155 covers the sacrificial patterns 152, and the insulating sustaining layer 154 is interposed between the metal-organic dielectric material 155 and the metal-organic dielectric material 155. A thickness T1′ of the metal-organic dielectric material 155 may be in a range of 30 nm to 130 nm depending on IC layout pattern design. In some embodiments, a ratio (H′/T1′) of a thickness H′ of the sacrificial pattern 152 to the thickness T1′ of the metal-organic dielectric material 155 thereover may be in a range of 0.04 to 0.48.

Referring to FIG. 6B, the sacrificial patterns 152 are removed to form air gaps 158. The air gaps 158 are formed below the metal-organic dielectric material 155, for example. In some embodiments, the sacrificial patterns 152 are removed immediately after the formation of the metal-organic dielectric material 155. The sacrificial patterns 152 may be removed by a thermal process such as a thermal baking process, an UV curing process or the like. In some embodiments, since both the density of the metal-organic dielectric material 155 and the insulating sustaining layer 154 is low, the sacrificial patterns 152 are removed by evaporating through the metal-organic dielectric material 155 and the insulating sustaining layer 154 when heating by the thermal process. In other words, the sacrificial patterns 152 may be removed with the presence of the metal-organic dielectric material 155 and the insulating sustaining layer 154 thereabove. In alternative embodiments, an additional UV curing may be performed to ensure complete removal of sacrificial material without any residual carbon content in the trench 159 (shown in FIG. 1I). In some embodiments, a ratio (H/T1′) of a height H of the air gap 158 to the thickness T1′ of the metal-organic dielectric material 155 thereover may be in a range of 0.04 to 0.48.

Referring to FIG. 6C, the metal-organic dielectric material 155 is partially removed to form a plurality of metal-organic dielectric layers 156. In some embodiments, the portions of the metal-organic dielectric material 155 and the hard mask layers 146 higher than the sacrificial patterns 144 are removed. The removal may be performed by etch process such as dry etch process or wet etch process, a planarization process such as chemical mechanical planarization (CMP) process or any suitable process. In some embodiments, a ratio (H/T1) of the height H of the air gap 158 to the thickness T1 of the metal-organic dielectric layer 156 thereover may be in a range of 0.25 to 1.5.

Then, the sacrificial patterns 144 are replaced with conductive features 164, and a conductive feature 172 in a dielectric structure 166 is formed over the dielectric structure 160 and electrically connected to the conductive feature 164, to form an interconnect structure INS of FIG. 1K (with rounded corner 162) or FIG. 2 (without rounded corner 162), for example.

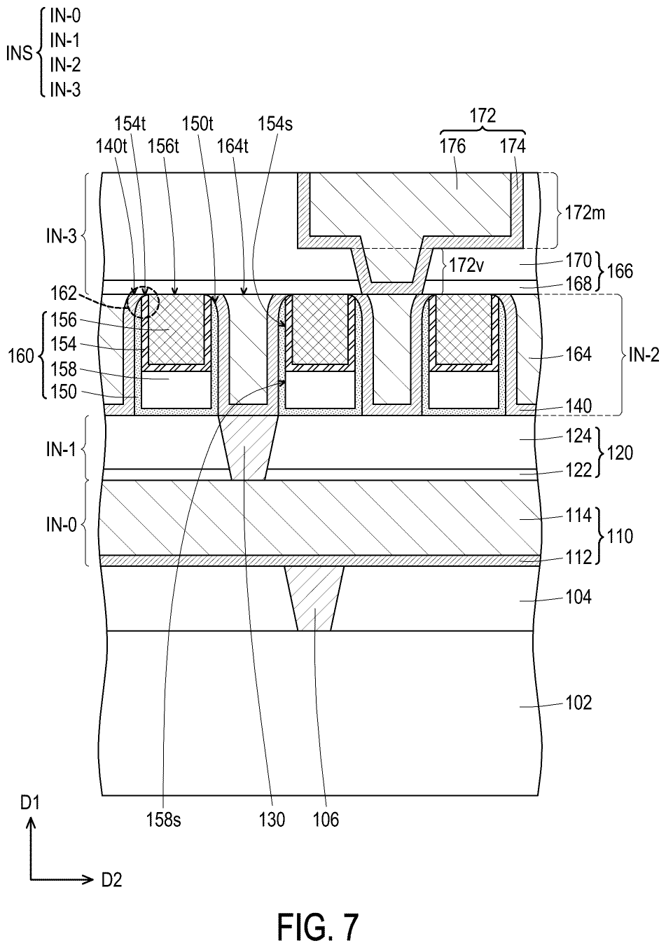

In the above embodiments, the conductive layer 140 is formed before the formation of the sacrificial pattern 144 and is remained in the subsequent process. However, the disclosure is not limited thereto. In alternative embodiments, the conductive layer 140 may be formed after the trench 159 is formed (i.e., after the sacrificial pattern 144 are removed). In such embodiments, as shown in FIG. 7, the conductive layer 140 is formed to surround the conductive feature 164. For example, surfaces (e.g., top surfaces) 140t, 164t of the conductive layer 140 and the conductive feature 164 are substantially coplanar with a surface (e.g., top surface) 156t of the metal-organic dielectric layers 156.

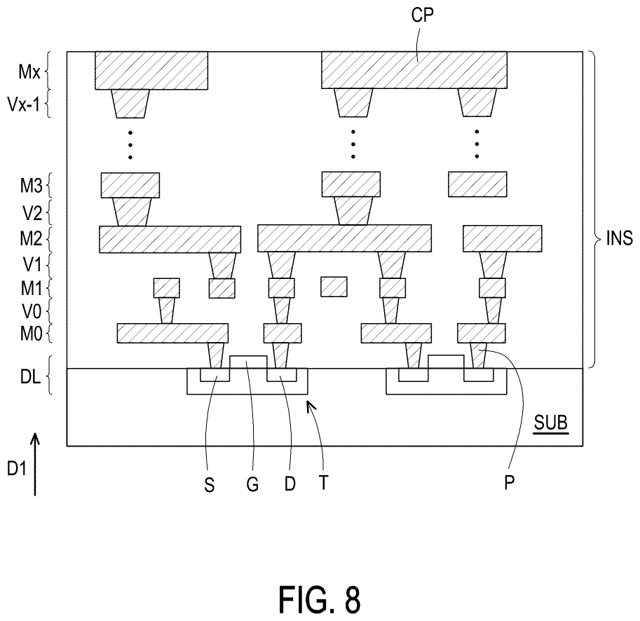

FIG. 8 illustrates a cross-sectional view of a semiconductor device according to some embodiments.

In some embodiments, a semiconductor device includes a substrate SUB, a device layer DL and an interconnect structure INS. The semiconductor device may be a dynamic random access memory (DRAM) die, a static random access memory (SRAM) die or a high bandwidth memory (HBM) die, an application-specific integrated circuit (ASIC) die, an application processor (AP) die, a system on chip (SoC) die or a high performance computing (HPC) die, but the disclosure is not limited thereto. The substrate SUB may be similar to the substrate 102. The device layer DL is disposed between the substrate SUB and the interconnect structure INS. The device layer DL may be disposed in and/or on the substrate SUB and include an active device (e.g., a transistor T), a passive device (e.g., a resistor, a capacitor, or an inductance), or a combination thereof. The transistor T may include a gate G and a source S and a drain D at opposite sides of the gate G. The device layer DL may be formed using front-end of line (FEOL) fabrication techniques. The interconnect structure INS may be formed using back-end of line (BEOL) fabrication techniques and may be electrically coupled to a corresponding device layer DL.

The interconnect structure INS may include a plurality interconnect layers M0, M1 . . . Mx including conductive lines and a plurality interconnect layers V1, V2 . . . or V(x−1) including conductive vias and disposed in adjacent two interconnect layers M0, M1 . . . Mx. In some embodiments, at least one of the interconnect layers M0, M1 . . . Mx is formed as the interconnect layer IN-2 of IFG. In some embodiments, the topmost interconnect layer Mx in the interconnect structure INS may include a plurality of conductive pads CP. The conductive pad CP may be a signal pad (e.g., an I/O pad) or a ground pad. In some embodiments, the bottommost interconnect layer M0 in the interconnect structure INS is electrically connected a corresponding region (e.g., the source S, the drain D, or the gate G of the transistor T) of the device layer DL by a conductive feature (e.g., a plug P).

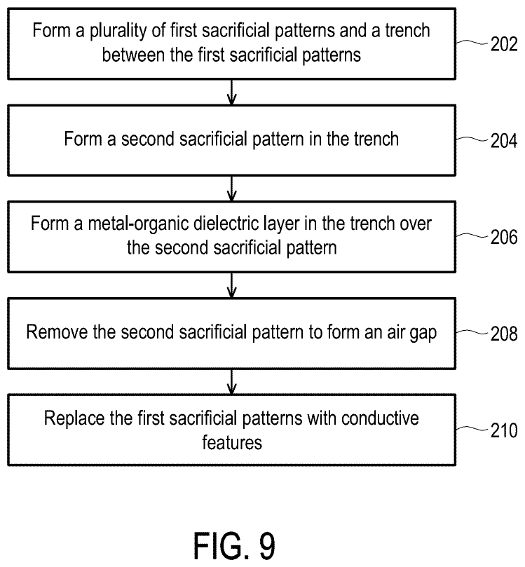

FIG. 9 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 202, a plurality of first sacrificial patterns and a trench between the first sacrificial patterns are formed. FIG. 1B, FIG. 5A, FIG. 6A and FIG. 6C illustrate views corresponding to some embodiments of act 202.

At act 204, a second sacrificial pattern is formed in the trench. FIG. 1D, FIG. 5A and FIG. 6A illustrate views corresponding to some embodiments of act 204.

At act 206, a metal-organic dielectric layer is formed in the trench over the second sacrificial pattern. FIG. 1F to FIG. 1G, FIG. 5A and FIG. 6A illustrate views corresponding to some embodiments of act 206.

At act 208, the second sacrificial pattern is removed to form an air gap. FIG. 1H, FIG. 5C and FIG. 6B illustrate views corresponding to some embodiments of act 208.

At act 210, the first sacrificial patterns are replaced with conductive features. FIG. 1I to FIG. 1J and FIG. 5B illustrate views corresponding to some embodiments of act 210.

In accordance with some embodiments of the disclosure, a semiconductor device includes a first conductive feature, a second conductive feature and a dielectric structure. The dielectric structure is laterally disposed between the first conductive feature and the second conductive feature. The dielectric structure includes a metal-organic dielectric layer a metal-organic dielectric layer and an air gap disposed below the dielectric layer.

In accordance with some embodiments of the disclosure, a semiconductor device includes an interconnect structure including a dielectric structure. The dielectric structure includes a metal-organic dielectric layer, an air gap and an insulating sustaining layer. The insulating sustaining layer surrounds the metal-organic dielectric layer and the insulating sustaining layer is disposed between the metal-organic dielectric layer and the air gap.

In accordance with some embodiments of the disclosure, a method of forming a semiconductor device includes the following steps. A plurality of first sacrificial patterns and a trench between the first sacrificial patterns are formed. A second sacrificial pattern is formed in the trench. A metal-organic dielectric layer is formed in the trench over the second sacrificial pattern. The second sacrificial pattern is removed to form an air gap. The first sacrificial patterns are replaced with conductive features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first conductive feature;
a second conductive feature;
a dielectric structure, laterally disposed between the first conductive feature and the second conductive feature, wherein the dielectric structure comprises:
a metal-organic dielectric layer; and
an air gap disposed below the dielectric layer.

2. The semiconductor device of claim 1, wherein the metal-organic dielectric layer comprises a metal organic framework (MOF).

3. The semiconductor device of claim 1, wherein a first surface of the dielectric structure is substantially coplanar with a first surface of the first conductive feature.

4. The semiconductor device of claim 1, wherein a thickness of the metal-organic dielectric layer is larger than a height of the air gap.

5. The semiconductor device of claim 1, wherein a lateral dimension of the metal-organic dielectric layer between the first and second conductive features is smaller than a lateral dimension of the air gap between the first and second conductive features.

6. The semiconductor device of claim 1, further comprising:
an insulating sustaining layer, surrounding the metal-organic dielectric layer, and disposed between the metal-organic dielectric layer and the first conductive feature, between the metal-organic dielectric layer and the second conductive feature and between the metal-organic dielectric layer and the air gap.

7. The semiconductor device of claim 6, wherein a sidewall of the insulating sustaining layer is substantially flush with a sidewall of the air gap.

8. The semiconductor device of claim 6, further comprising:
a dielectric capping layer, surrounding the metal-organic dielectric layer and the air gap, and disposed between the insulating sustaining layer and the first conductive feature and between the insulating sustaining layer.

9. The semiconductor device of claim 1, wherein an upper portion of the dielectric structure has a rounded corner.

10. A semiconductor device, comprising:
an interconnect structure, comprising a dielectric structure, wherein the dielectric structure comprises:
a metal-organic dielectric layer;
an air gap; and
an insulating sustaining layer, wherein the insulating sustaining layer surrounds the metal-organic dielectric layer, and the insulating sustaining layer is disposed between the metal-organic dielectric layer and the air gap.

11. The semiconductor device of claim 10, wherein the insulating sustaining layer is disposed on sidewalls and a bottom surface of the metal-organic dielectric layer.

12. The semiconductor device of claim 10, wherein a sidewall of the insulating sustaining layer is substantially flush with a sidewall of the air gap.

13. The semiconductor device of claim 10, wherein a surface the insulating sustaining layer is lowered than a surface of the metal-organic dielectric layer.

14. The semiconductor device of claim 10, wherein a surface the insulating sustaining layer is substantially coplanar with a surface of the metal-organic dielectric layer.

15. The semiconductor device of claim 10, further comprising:
a dielectric capping layer, surrounding the insulating sustaining layer and the air gap, wherein the insulating sustaining layer is disposed between the metal-organic dielectric layer and the dielectric capping layer.

16. The semiconductor device of claim 15, wherein a surface the dielectric capping layer is lowered than surfaces of the metal-organic dielectric layer and the insulating sustaining layer.

17. The semiconductor device of claim 10, wherein the interconnect structure further comprises a plurality of conductive features separated by the dielectric structure.

18. A method of forming a semiconductor device, comprising:
forming a plurality of first sacrificial patterns and a trench between the first sacrificial patterns;
forming a second sacrificial pattern in the trench;
forming a metal-organic dielectric layer in the trench over the second sacrificial pattern;
removing the second sacrificial pattern to form an air gap; and
replacing the first sacrificial patterns with conductive features.

19. The method of claim 18, further comprising:
after forming the second sacrificial pattern, forming an insulating sustaining layer on sidewalls of the trench and on the second sacrificial pattern.

20. The method of claim 18, further comprising:
before forming the second sacrificial pattern, forming a dielectric capping layer on sidewalls and a bottom surface of the trench.
